(19) United States
(12) Patent Application Publication
(10) Pub. No.: US 2018/0164003 A1
(43) Pub. Date: Jun. 14, 2018

(54) Temperature Control Unit for Gaseous or Liquid Medium

(71) Applicant: AVL LIST GmbH, Graz (AT)

(72) Inventors: Vedran Burazer, Graz (AT); Michael Buchner, Graz (AT)

(21) Appl. No.: 15/739,521

(22) PCT Filed: Jun. 21, 2016
(86) PCT No.: PCT/EP2016/064300

§ 371 Date: Dec. 22, 2017

(30) Foreign Application Priority Data
Jun. 23, 2015 (AT) A50532/2015

(51) Int. Cl. F25B 21/04; H01L 35/32; F02M 31/125; F23K 1/04; F23K 5/02; F23K 5/00

(52) U.S. Cl. CPC F25B 21/04; H01L 35/32; F02M 31/125; F23K 1/04; F23K 5/02; F25B 2321/003; F25B 2321/023; F25B 2321/0251; F25B 2321/0252; F23K 2301/10; F23K 2401/10; F23K 5/002

(57) ABSTRACT

For a temperature control unit for gaseous or liquid medium with a highly dynamic temperature regulation of the medium, the temperature control unit is designed with a base body and a cooling body between which are arranged multiple thermoelectric modules, and with a media line in the base body, wherein the media line is arranged in the base body in the form of a single-start spiral from the outside to the inside, and it is provided that the multiple thermoelectric modules are arranged in a plurality of rows on the base body, wherein the module heating power of a thermoelectric module situated further toward the outside radially is greater than the module heating power of a thermoelectric module situated further toward the inside radially.

### TECHNICAL FIELD

The present invention relates to a temperature control unit for temperature control of a gaseous or liquid medium by means of a number of thermoelectric modules which are arranged between a base body and a cooling body, and a media line being arranged in the base body, through which the gaseous or liquid medium flows, wherein the media line is arranged in the base body in the form of a single-start spiral from the outside to the inside.

### BACKGROUND

For accurate measurement of the fuel consumption of an internal consumption engine on a test stand, accurate conditioning of the temperature and pressure of the fuel supplied to the internal combustion engine is necessary. The fuel consumption is often measured using a known Coriolis flow sensor. An example of such a measurement of fuel consumption can be found in US 2014/0123742 A1, which is based on conditioning of liquid fuels. In that application, the temperature of the fuel is regulated by means of a heat exchanger using a cooling liquid. Extreme changes in load cause extreme fluctuations in fuel consumption and in the media temperature of the return flow (input temperature). However, such a heat exchanger is slow, allowing only gradual changes in temperature. Thus, the conditioning by means of a heat exchanger that has been described is not suitable for extreme load changes (changes in input temperature). With the current state of the art, this leads to the result that it is necessary to allow a settling time after such a load change. During this period of time, the temperature is not stable, and a high-precision measurement is impossible with flow sensors. For operation that is independent of the changes in input temperature, one option is to increase the power density of the heat exchanger. But this is not readily feasible technically and would require a redesign of the heat exchanger, if it were possible at all. If the power density remains the same, this would result in a need for a much larger amount of space. Another possibility might consist of a more aggressive control of the heat exchanger, but this in turn would mean greater overshooting and undershooting, and, associated therewith, inferior dynamics with respect to possible changes in the setpoint temperature. However, increasing the size of the heat exchanger would also be helpful only in the case of liquids. In the case of gaseous media, a change in flow would immediately cause a change in pressure and a change in setpoint temperature. The heat exchanger would therefore have to enable extremely fast changes in setpoint temperature, but this cannot be achieved in practical terms for a heat exchanger operated with a cooling liquid. To do so, the available power would have to be further increased at the same mass, but merely increasing the power would be of no benefit in this case. A remaining alternative is to adjust the controller of the heat exchanger to be more aggressive, although that would in turn result in even greater undershooting and overshooting. Rapid and precise temperature control would be impossible in this way.

Dynamic temperature regulation by means of a heat exchanger is also relatively inaccurate, i.e., if a constant temperature is not to be set. Apart from this, such a heat exchanger would necessitate additional parts and controllers for operating the heat exchanger, which would also make the plant more expensive.

DE 10 2010 046 946 A1 proposes controlling the temperature of the fuel in a conditioning plant by means of thermoelectric modules (so-called Peltier elements). Thus, because of the low storage masses achieved, a highly dynamic temperature control is possible, whereby the fuel can be both heated and cooled. This apparatus is also aimed specifically at conditioning liquid fuels.

There is the additional problem with gaseous fuels such as natural gas or hydrogen that the gaseous fuel is usually available or supplied at a high pressure and consequently must first be depressurized to a lower pressure, which is required for use as a fuel in an internal combustion engine. However, when the gaseous fuel such as natural gas is depressurized, the fuel cools down drastically, which can be problematic for downstream components of the conditioning plant, for example, due to the formation of condensate and ice on the gas lines or other components in the gas line. Therefore, the gaseous fuel is usually heated before being depressurized, so that the desired temperature of the fuel is achieved by decompression. Because of the fluctuations in pressure of the gaseous fuel supplied and also because of the dependence of temperature after decompression on the composition of the gaseous fuel, which can also vary, the temperature control of the gaseous fuel must be highly dynamic prior to decompression in order to be able to maintain a constant temperature after decompression and before the flow measurement. In addition, the required heating power for temperature control of the fuel also depends greatly on the prevailing flow rate, which also necessitates a highly dynamic temperature control in the case of rapidly changing flow rates.

Such a highly dynamic temperature control necessitates, first of all, a control method that is capable of carrying out highly dynamic control intervention (in the sense of rapid changes in temperature), and secondly, a temperature control unit that is also capable of implementing the highly dynamic control interventions. Consequently, such a temperature control unit must be capable of impressing the required temperature changes in the flowing fuel within a very short period of time. In addition, a high thermal stability is also desired, even if under some circumstances high demands are not made on the dynamics of the temperature control, because certain applications require high precision and extremely constant control. These requirements necessitate a temperature control unit with a high heating and cooling power, but under some circumstances it may also be necessary to change rapidly between heating and cooling. Apart from this, an accurate temperature control must also be possible in order to prevent excessive overregulation of the temperature (either overheating or undercooling).

DE 10 2010 046 946 A1 gives the indication that for a highly dynamic temperature control, small thermal storage masses of the temperature control unit are advantageous.

U.S. Pat. No. 6,502,405 B1 discloses a heat exchanger element with Peltier elements for heating or cooling fuel in a vehicle. The heat exchanger element is composed of a thermal conduction block in which a fuel line is installed in a meandering layout and which is insulated thermally on a first side. Peltier elements, which are thermally connected to a cooling body, are located on the second side of the thermal conduction block. The cooling body is typically designed with a large surface area and a small storage mass in order to maximize the heat dissipation capacity. In addition, a fan is also provided on the cooling body in order to further increase the capacity for dissipation of heat. Thus, the heat exchanger element of U.S. Pat. No. 6,502,405 B1 is also designed for a low thermal storage mass in order to be able to rapidly dissipate the heat to the surroundings via the cooling body. Due to the meandering layout of the fuel line in the heat exchanger element, however, there is also an uneven heating of the fuel, which makes the temperature control more difficult because all of the Peltier elements are supplied with the same supply voltage. The uneven heating results in a higher temperature difference between the temperature of the medium at the outlet and the surface of the Peltier elements, which in turn leads to a lower maximum outlet temperature of the medium because the Peltier elements cannot be heated at will. Alternatively, there is a lower maximum flow rate at a predetermined setpoint outlet temperature. Apart from this, more thermal energy is stored in the heat conducting block due to the greater temperature difference. This thermal energy must be dissipated again when there is a change in the setpoint temperature, but that in turn makes the heat exchanger element slower. For a more uniform heating of the fuel, the individual Peltier elements would either have to be attuned to one another, i.e., different Peltier elements provided along the fuel line, or the Peltier elements would have to be supplied and regulated individually. However, both options would be very complicated and therefore disadvantageous.

However, the problems described above can basically occur with any gaseous or liquid medium of which the temperature is to be controlled in a temperature control unit, not just with fuels.

EP 003 822 A1 discloses a temperature control unit for the temperature control of a liquid flow that has a main heat exchanger, an auxiliary heat exchanger, and Peltier elements arranged therebetween. A media line for temperature control of a liquid flow is arranged in the main heat exchanger, and is in the form of a spiral from the outside to the inside. Preliminary temperature control takes place in the auxiliary heat exchanger, and the Peltier elements serve to accurately and rapidly control to a desired temperature.

Against the background of this prior art, it is an object of the present invention to provide a temperature control unit for a gaseous or liquid medium which permits a particularly highly dynamic and accurate temperature control of the medium.

### SUMMARY

This object is achieved according to the invention, through an aforementioned temperature control unit, by arranging the multiple thermoelectric modules in multiple rows on the base body, wherein the module heating power of a thermoelectric module situated further toward the outside radially is greater than the module heating power of a thermoelectric module situated further toward the inside radially. As a result, very efficient temperature control is achieved. The temperature of the medium flowing in from the outside can be controlled in the region of the high heating power on the outside radially, which permits rapid and strong changes in temperature. A “module heating power” of a thermoelectric module is, in the scope of the present disclosure, understood to be both the rated power at a rated voltage or rated current and the power that occurs at a certain supply voltage deviating from the rated voltage or a certain supply current deviating from the rated current. The modules are then preferably attuned to one another so that the temperature spread is minimal at the maximum flow rate between the module surface and the outlet temperature of the medium. It has been found that this is the case when all the modules are at approximately the same surface temperature. Due to the peripheral arrangement, the thermoelectric modules within one row are naturally almost at the same temperature. Only the different rows would have to be balanced in this regard, which is a significant simplification in contrast to a meandering arrangement of the media line, because it is no longer necessary for all the thermoelectric modules to be balanced for the same result to be achieved (minimum temperature spread).

Furthermore, the module heating power can be optimally adapted to the conditions, and modules having a lower module heating power can be installed on the inside radially.

If the heating power in the radially outer region of the base body, as the sum of the module heating powers of the thermoelectric modules in the radially outer region, is greater than the heating power in the radially inner region of the base body, as the sum of the module heating powers of the thermoelectric modules in the radially inner region, then the temperature control of the medium can also be optimized through the arrangement and selection of the module heating power of the individual thermoelectric modules and a very uniform heating of the medium can be achieved.

In other words, according to the invention, the multiple thermoelectric modules are arranged in a plurality of rows on the base body, and the module heating power of a thermoelectric module situated further toward the outside radially can be set to be greater than the module heating power of a thermoelectric module situated further toward the inside radially. To this end, the adjustability of the module heating power can be achieved both through the selection of modules with different rated powers and through different supply voltage/current values.

Due to the arrangement of the media line in the base body in the form of a single-start spiral, a particularly uniform and efficient temperature control of the medium can be achieved. Due to the spiral shape, the temperature control unit may be designed very compactly because the spiral passes can be arranged close to one another. Therefore, a thermoelectric module may also cover multiple spiral passes, which improves the efficiency of the temperature control unit and the uniformity in heating. This makes it possible to achieve a particularly highly dynamic and accurate and stable temperature regulation of the medium.

It is especially advantageous when the mass ratio of the thermal storage mass of the cooling body to the thermal storage mass of the base body and the media line arranged therein is in the range of 0.5 to 1, advantageously in the range of 0.7 to 0.8, and most especially advantageously selected to be 0.75. It has been found that for a highly dynamic temperature regulation of a medium by means of a temperature control unit according to the preamble of claim 1, in particular when a rapid and repeated change in direction of heat flow is necessary, it is a disadvantage for the storage mass to be too low, as suggested by the state of the art. It has surprisingly been found that a certain mass ratio between the mass of the cooling body and the mass of the base body together with the media line arranged therein is advantageous for the regulation of temperature. The reason for this is apparently the fact that due to the greater mass of the cooling body, a thermal storage mass is formed and therefore thermal energy is not released to the environment too rapidly. This stored energy can then be used for support in heating the fuel, so that the temperature control can be achieved more rapidly and with a greater precision.

A compact design of the temperature control unit is obtained when a groove into which the media line is pressed is provided in the base body.

To concentrate the thermal energy in the base body and to prevent an excessive drain of thermal energy, the base body is advantageously surrounded by a base body jacket, wherein a plurality of radial connecting webs which are connected to the base body jacket are arranged over the circumference of the base body. This also increases the efficiency of the temperature control unit. This can be further improved if the base body jacket is designed to be partially hollow, because this achieves even better thermal insulation between the base body and the surroundings.

It may be advantageous to arrange, in the cooling body, a cooling line through which cooling medium for cooling the cooling body flows as needed in order to be able to dissipate heat from the cooling body more rapidly. This may be useful in particular in the case of gases without a pronounced Joule-Thomson effect or with liquid media because in these cases, frequent reversal of polarity of the thermal modules may be necessary. The cooling line is then advantageously again arranged in a spiral.

### BRIEF DESCRIPTION OF THE DRAWINGS

The present invention shall be described in further detail herein below with reference to FIGS. 1 to 7, which illustrate advantageous embodiments of the present invention by way of example, in a schematic and non-limiting manner. In the drawings,

FIG. 1 shows a perspective view of the temperature control unit according to the invention,

FIG. 2 shows a view of a temperature control unit with the cooling body removed,

FIGS. 3 and 4 show views of the base body of a temperature control unit,

FIG. 5 shows a view of the media line in the temperature control unit,

FIG. 6 shows another advantageous arrangement of the media line in the base body, and

FIG. 7 shows a temperature control unit with a cooling line in the cooling body.

### DETAILED DESCRIPTION

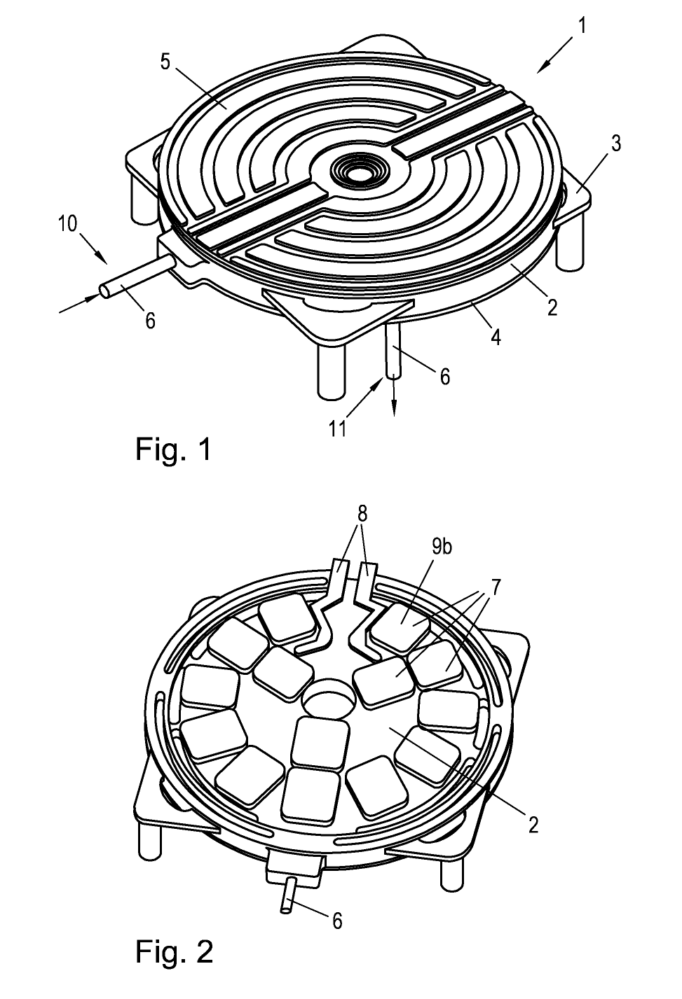

FIG. 1 shows a perspective view of the temperature control unit 1 according to the invention. The temperature control unit 1 is composed of a base body 2 on which any fastening elements 3, such as, for example, feets in the exemplary embodiment shown here, may also be provided for fastening the temperature control unit 1. A thermal insulation element 4 is arranged on a first side of the base body 2, and a cooling body 5 is arranged on the opposite second side. A media line 6 is passed through the temperature control unit 1 through which flows a gaseous or liquid medium such as a fuel of which the temperature is controlled at a desired level in the temperature control unit 1. The media line 6 therefore has an input connection 10 and an output connection 11, so that the direction of flow of the medium through the temperature control unit 1 is defined (indicated by arrows in FIG. 1).

FIG. 2 shows the temperature control unit 1 with the cooling body 5 removed. A number of thermoelectric modules (Peltier elements) 7, which are arranged on the base body 2, can be seen therein. A thermoelectric module 7 is known to be a semiconductor element, which is arranged between a first heating surface 9a (facing the base body 2 here, but not visible in FIG. 2) and a second heating surface 9b (facing the cooling body 5 here). Depending on the polarity of the electric voltage supplied to the semiconductor element, either the first heating surface 9a is hotter than the second heating surface 9b or vice versa. Since the design and function of such thermoelectric modules 7 are sufficiently well known and such thermoelectric modules 7 are available commercially in various power classes, they will not be discussed in greater detail here.

Thus, depending on the polarity of the power supply voltage, which is supplied, for example, via terminals 8, it is possible to provide both heating and cooling with such a thermoelectric module 7. “Heating” here means that heat is supplied to the base body 2, and “cooling” means that heat is withdrawn from the base body 2. The heat flow between the base body 2 and the cooling body 5 can thus be influenced with the thermoelectric modules 7.

The thermoelectric modules 7 are in direct or indirect (for example, via a heat transfer element to improve the thermal conduction) thermal contact with the base body 2 via a first heating surface 9a (not visible in FIG. 2). The cooling body 5 is arranged on the second heating surface 9b of the thermoelectric module and is in thermally conductive contact either directly or indirectly with the second heating surface 9b. The cooling body 5 and the base body 2 are not arranged next to one another, in order to prevent direct thermally conductive contact between the cooling body 5 and base body 2 (as can be seen in FIG. 1).

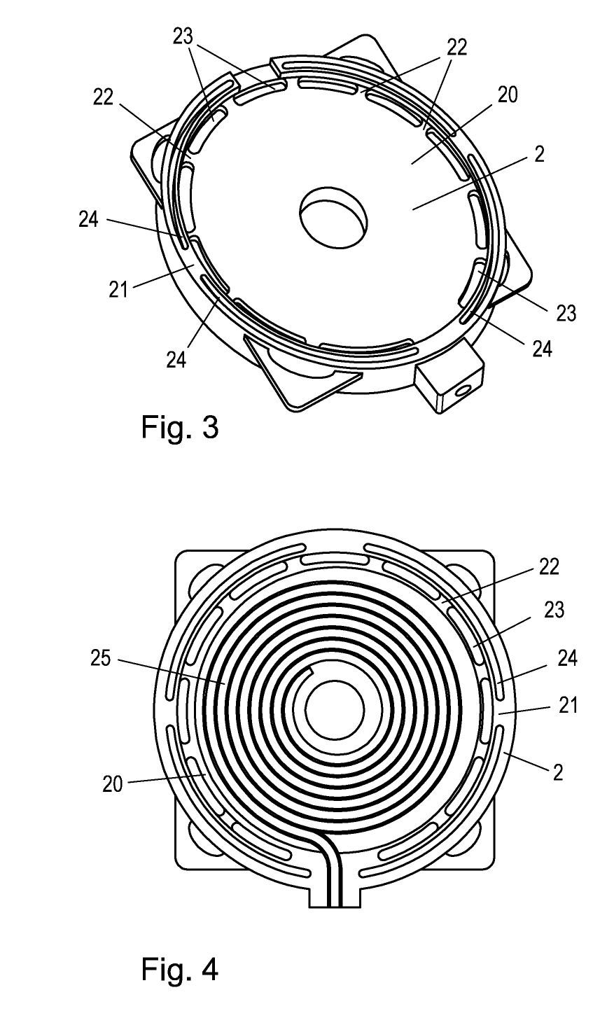

The base body 2 is illustrated in detail in FIGS. 3 and 4, which show different views of the base body 2. FIG. 3 shows the side of the base body 2 on which the thermoelectric modules 7 are arranged. The base body 2 is made substantially of a base plate 20, which is surrounded along its circumference by a base body jacket 21. The base body jacket 21 is connected to the base plate 20 by radial connecting webs 22, wherein the connecting webs 22 are arranged so as to be distributed around the circumference of the base plate 20. In the circumferential direction between the connecting webs 22, cavities 23 are formed, functioning as thermal insulation between the base plate 2 and the base body jacket 21. The heat flow from the base plate 20 into the base body jacket 21 is greatly reduced by the connecting webs 22 and the cavities 23. Therefore, the heat introduced by the thermoelectric modules 7 into the base plate 20 remains concentrated there and flows only to a minor extent through the base body jacket 21 to the surroundings. This, at the same time, also achieves the goal that the base body jacket 21 and thus also the temperature control unit 1 are not heated too greatly on the outside and that parasitic heat flows, which would reduce the power and dynamics of the conditioning, are minimized as much as possible.

The base body jacket 21 may additionally be designed to be partially hollow, by incorporation of peripheral slots 24 into the base body jacket 21, also forming cavities for additional thermal insulation.

FIG. 4 shows the other side of the base body 2, where it can be seen that a preferably spiral groove 25 into which the media line 6 is pressed in the assembled state is formed on the backside of the base plate 20. The groove 25 here forms a single-start planar spiral (Archimedean spiral, logarithmic spiral) in the base body 2. The media line 6 is preferably guided in a spiral pattern from the outside to the inside, emerging from the temperature control unit 1 in the inner central region of the base plate 20, wherein the media line 6 is bended, preferably by approx. 90°, out of the plane of the spiral on its exit in order to easily lead the media line 6 out from the temperature control unit 1. Basically, however, any other type of guidance of the media line 6 in the base body 20 is also conceivable.

The use of a media line 6 in the form of a single-start spiral is very complex from the standpoint of manufacturing technology because in this case the media line 6 extends in all three dimensions.

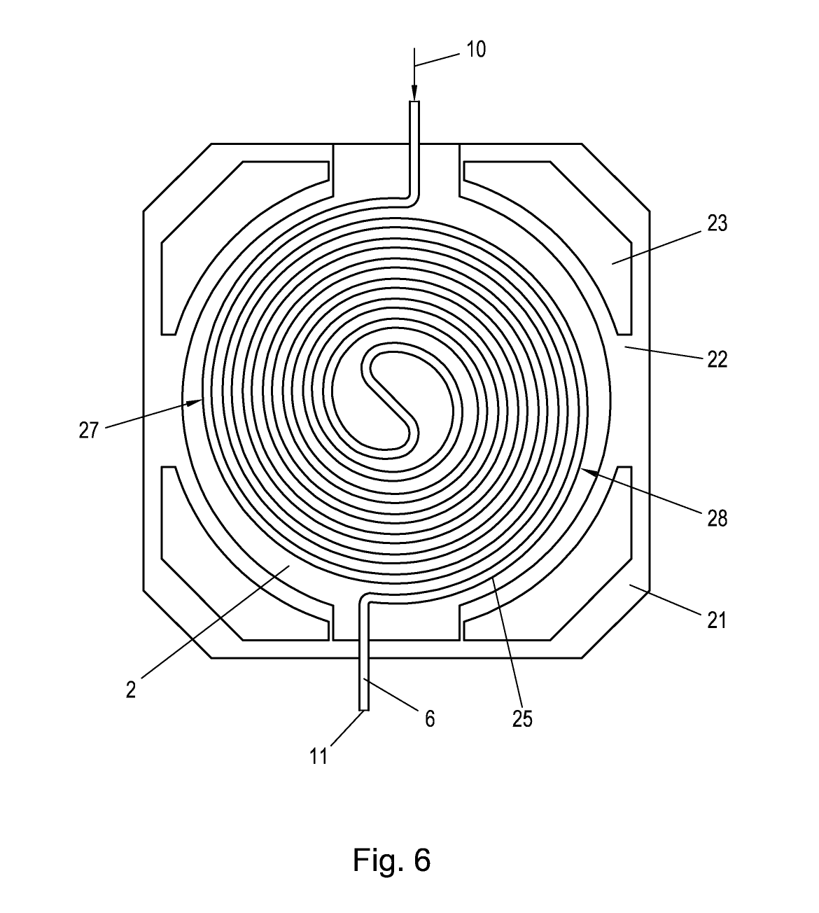

In an alternative embodiment, the media line 6 is arranged on the base body 2 in the form of a two-start planar spiral (also known as Fermat's spiral), as described with reference to FIG. 6. Again, a suitably shaped groove 25 to receive the media line 6 may be formed in the base body 2 for this purpose. The medium is supplied in a spiral pattern in the media line 6 from the outside radially to the inside centrally via a first spiral pass 27. On the inside centrally, the first spiral pass 27 is connected to a second spiral pass 28 through which the medium is carried in the media line 6 from the inside radially to the outside radially in a spiral pattern. A first spiral pass 27 and a second spiral pass 28 are always situated radially side-by-side due to the two-start design of the groove 25. The medium is thus supplied on the outside radially through the input connection 10 and removed on the outside radially via the output connection 11. The two-start spiral has an advantage in that the media line 6 need not be bended out of the plane of the spiral, which is simpler in terms of the manufacturing technology. The two-start spiral, however, has a disadvantage in that the medium flowing in cools the medium flowing out, so somewhat more power is needed and the resulting heating achieved is less uniform. The temperature spread is in this case greater, but the thermoelectric modules of one row will all still be at approximately the same temperature, in the case of attuned modules.

The single-start or two-start spiral need not necessarily be designed as a circular spiral but instead may also have other shapes such as rectangular, square, etc. Due to the spiral shape, the temperature control unit 1 can have a very compact design because the spiral passes can be arranged close to one another. Therefore, a great many running meters of media line 6 can be accommodated in a small space, which increases the available surface for temperature control of the medium flowing through the media line 6.

To be able to implement a dense packing of the media line 6, bending radii must not come below stipulated minimum bending radii in the shaping of the media line 6. A meandering layout of the media line would be disadvantageous in this regard because the required bending radii for a dense packing are considerably smaller than those with a spiral layout. With increasing pressure demands with regard to the media line 6, the minimum bending radius usually also increases because of the required increase in wall thickness. Therefore, a meandering layout has a particularly negative effect when there are high pressure demands, as in the present case.

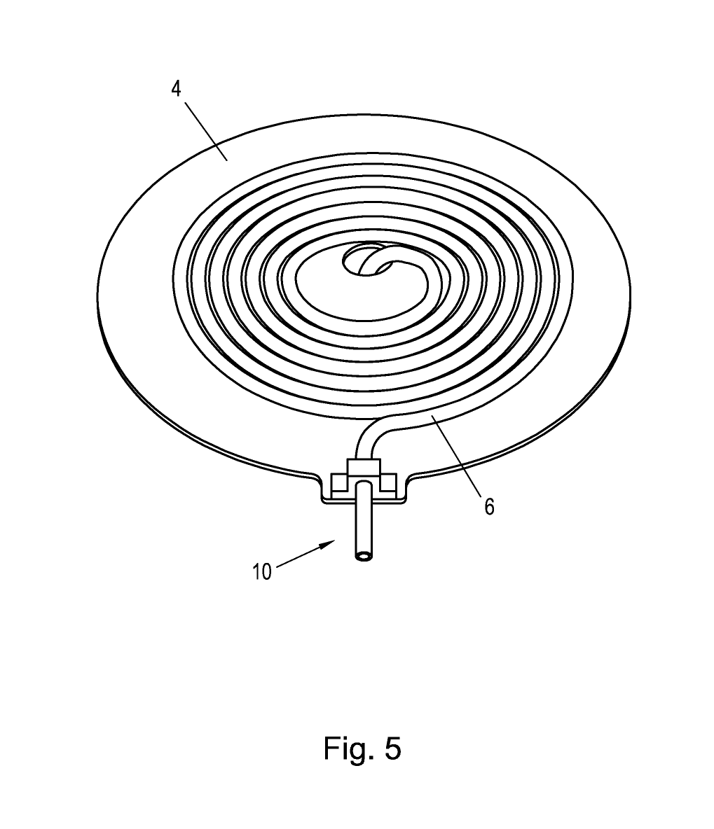

FIG. 5 shows the thermal insulation element 4 with the media line 6, which is advantageously a spiral-shaped single-start line, that is pressed into the base body 20 in the assembled state. Due to the thermal insulation element 4, it is achieved that the heat introduced by the thermoelectric modules 7 into the base plate 20 remains concentrated therein and is not discharged to the surroundings via the end face of the temperature control unit 1.

The thermoelectric modules 7 are preferably arranged on the base plate 20 in the form of circles, or adapted to the spiral form, and in multiple rows (that is at various radial distances) (FIG. 2). Therefore, more thermoelectric modules 7 may be arranged on the outside radially because of the resulting larger circumference. The inflowing medium is thus thermally controlled in the outer radial region with great heating power (sum of the module heating powers of the involved radially outer modules 7), which permits strong and rapid changes in temperature. It is also advantageous in this regard if a thermoelectric module 7 which is arranged farther toward the inside radially has a lower module heating power than a thermoelectric module 7 arranged farther to the outside radially. Since the media line 6 is preferably guided to the inside in a single-start spiral, fewer and weaker (in the sense of less module heating power) thermoelectric modules 7 on the inside radially are sufficient for temperature control on the medium. The heating power that is necessary radially inward (sum of the module heating powers of the involved radially inner modules 7) is therewith lower than the heating power in the radially outer region. Thus, the temperature control of the medium can also be optimized by the arrangement and choice of the module heating power of the individual thermoelectric modules 7 and a very uniform heating of the medium can be achieved.

The “module heating power” of a thermoelectric module 7 is generally understood to be the rated power at a rated current/rated voltage, as well as the power that occurs at a certain current/voltage deviating from the rated current/rated voltage. Consequently, according to the invention, thermoelectric modules 7 with different rated powers, thermoelectric modules 7 that can be adjusted differently with different or identical rated powers, or combinations thereof may be used.

If an electric power supply voltage is applied to a thermoelectric module 7, then as is known one of the heating surfaces 9a, 9b of the thermoelectric module 7 is cooled off while at the same time the opposing heating surface 9a, 9b is heated. The maximum temperature spread between the heating surfaces 9a, 9b depends on the operating temperature (temperature on the warmer heating surface) of the thermoelectric module 7. The higher the operating temperature, the higher the maximum achievable temperature spread between the cold and hot heating surfaces 9a, 9b. Therefore, with the available thermoelectric modules 7, temperatures of up to 200° C. can be achieved on the hot heating surface, with the cold heating surface not exceeding 100° C. A highly dynamic regulation of the temperature is made possible by simply reversing the polarity of the power supply voltage. This regulation is supported in the temperature control unit 1 according to the invention, in that the cooling body 5 is used as a buffer storage in heating operation, i.e., when the medium in the media line 6 is to be heated. To this end the thermal storage mass, however, should not be designed to be as small as possible as is suggested in the prior art, but instead a certain storage mass is desired in order to achieve this.

It has been found to be advantageous if the mass ratio of the thermal storage mass of the cooling body 5 to the thermal storage mass of the base body 2 and the media line 6 arranged therein is selected to be in the range of 0.5 to 1, advantageously 0.7 to 0.8. A most especially advantageous temperature regulability of the temperature control unit 1 was achieved at a mass ratio in the range of 0.75 or at a mass ratio of 0.75. A tested temperature control unit 1, for example, had a thermal storage mass of the cooling body 5 of 5.4 kg and a thermal storage mass of the base body 2 and the media line 6 arranged therein of 7.2 kg, which yields a mass ratio of 0.75.

In one embodiment as shown in FIG. 3 or FIG. 6, in which the base body jacket 21 is thermally separated from the base body 2 by means of cavities 23, the mass of the base body jacket 21 is not attributed to the thermal storage mass of the base body 2. Likewise, the insulation element 4 is not part of the thermal storage mass of the base body 2.

At a constant heating demand of the temperature control unit 1, i.e., at a constant power supply voltage of the thermoelectric module 7, a stable temperature spread is established on the thermoelectric modules 7. As soon as less thermal energy or heat for temperature control of the medium is needed, the power supply voltage to the thermoelectric modules 7 is reduced so that the temperature spread also becomes lower. The temperature on the heating surface 9a of the thermoelectric module 7, which is in contact with the base plate 20, therefore drops. At the same time, the temperature on the opposite heating surface 9b rises. Thus, there is a temperature gradient between the heating surface 9b and the cooling body 5, which is adjacent thereto, so that heat flows into the cooling body 5 and is not dissipated to the surroundings immediately because of the thermal storage mass of the cooling body 5, but instead is stored temporarily (at least for a limited period of time). This temporarily stored thermal energy is available to the temperature control or temperature control unit 1 as support when more thermal energy is again needed for temperature control of the medium. In this case, the power supply voltage would be raised again so that the temperature spread on the thermoelectric modules 7 would increase again. The temperature on the heating surface 9b with which the cooling body 5 is in contact would thus drop in comparison with the temperature of the cooling body 5. This results in an inverted temperature gradient, thus resulting in thermal energy (heat), which is stored in the cooling body 5, then flowing into the base body 2 and thus supporting the thermoelectric modules 7. Because of the thermal storage mass of the cooling body 5, it is possible for the temperature control unit 1 to respond very rapidly and precisely to load changes or changes in temperature, and the typical overshooting temperature control can be prevented to the greatest extent. However, this requires the thermal storage mass of the cooling body 5 to be not too large or too small in comparison to the thermal storage mass of the base body 2 and the media line 6 arranged therein.

The total surface area of the cooling body 5 should be designed as a function of the operating temperature to be expected, so that the heat stored in the cooling body 5 is not dissipated too rapidly to the surroundings but instead remains stored in the cooling body 5 for a sufficient period of time. The surface is therefore not to be dimensioned to be as large as possible and optimized for the dissipation of heat, as it would be in a traditional cooling body, but on the contrary, it is to be dimensioned so that the heat remains stored in the cooling body 5.

Complete thermal insulation of the cooling body 5 from the surroundings would also be disadvantageous because in the case of frequent reversals of polarity, the temperature in the cooling body 5 might escalate.

For various media, the material of the media line 6 and the heating power of the thermoelectric modules 7 or the module heating powers of the thermoelectric modules 7 may optionally be adapted. However, the general basic principle with the cooling body 5 as a storage mass for support of the temperature control unit 1 remains unaffected.

For certain gaseous media such as natural gas, there is a great cooling in accordance with the Joule-Thomson effect due to the required depressurization. With these gases, the temperature control unit 1 must usually only preheat the gaseous medium. Cooling of these gases by the temperature control unit 1 is usually not necessary. Therefore, it is normally also sufficient for these applications to work only with the temperature spread of the thermoelectric modules 7. Reversal of the polarity to switch from heating to cooling is rather not necessary.

Other gaseous media, such as hydrogen, do not have this pronounced effect of extreme cooling due to the required depressurization. On the contrary, there may even be a heating due to depressurization. In temperature control of liquid media, often no depressurization is necessary because the liquid medium is already at the correct pressure.

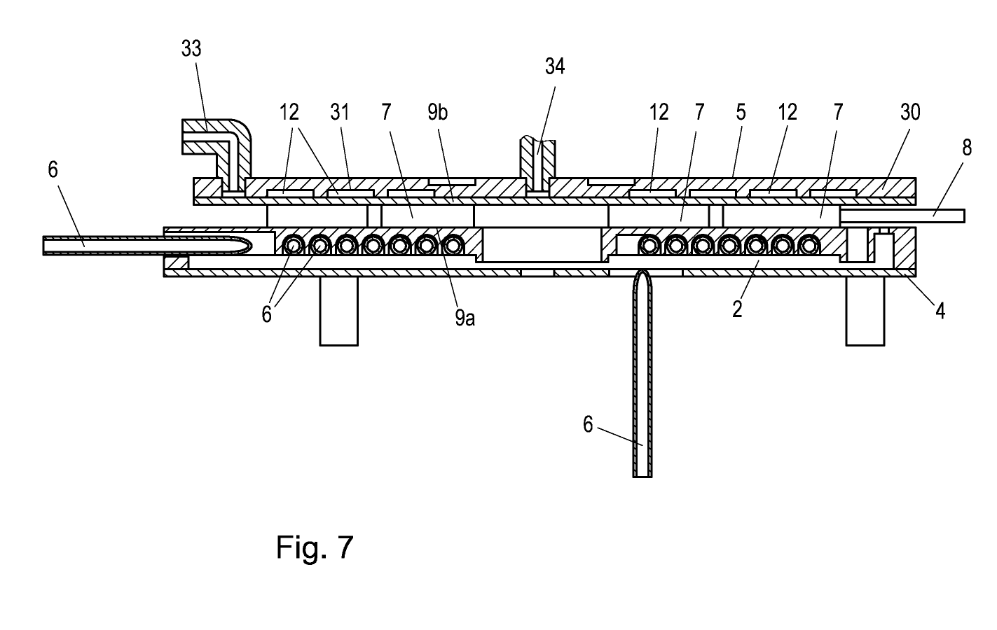

In the case of gases without a pronounced Joule-Thomson effect or with liquid media, the temperature control unit 1 therefore must often switch between heating and cooling the gaseous medium in order to keep the temperature constant as a function of the pressure and the flow rate. In particular in the case of cooling, however, it may happen that because of the lower surface area of the cooling body 5, the produced heat, in particular the waste heat of the thermoelectric modules 7, cannot be dissipated rapidly enough. Therefore, when the temperature control unit 1 is being used with such gaseous or liquid media, provisions may also be taken to additionally cool the cooling body 5 as needed. Therefore, a cooling line 12 may be introduced into the cooling body 5 through which a cooling liquid is conducted for the additional cooling of the cooling body 5. Such a design is indicated in FIG. 7. The cooling line 12 may again be arranged in the cooling body 5 in the form of a single-start or two-start spiral as described above with respect to the media line 6. Therefore, the cooling body 5 may also be designed in multiple parts in order to be able to introduce the cooling line 12. However, other embodiments of the cooling line 12 are of course also conceivable.

In the exemplary embodiment shown in FIG. 7, grooves 31 are formed into a cooling body base body 30, for example by milling, in order to form the cooling line 12. The grooves 31 are preferably cut in the form of spirals, as described above. The cooling body base body 30 with the grooves 31 is covered with a cooling body cover 32 in order to form the cooling body 5.

If a separate line is used as cooling line 12 in the cooling body 5 (like the media line 6 in the base body), then the cooling line 12 would also be part of the thermal storage mass of the cooling body 5.

To be able to connect the cooling line 12 in the cooling body 5, a cooling medium supply connection 34 and a cooling medium removal connection 33 may be provided on the cooling body. The cooling medium is preferably supplied centrally from the inside and discharged at the outside.

1. A temperature control unit for temperature control of a gaseous or liquid medium by means of a number of thermoelectric modules which are arranged between a base body and a cooling body, and a media line through which the gaseous or liquid medium flows being arranged in the base body, wherein the media line is arranged in the base body in the form of a single-start spiral from the outside to the inside, wherein the multiple thermoelectric modules are arranged in a plurality of rows on the base body, wherein the module heating power of a thermoelectric module arranged further toward the outside radially is greater than the module heating power of a thermoelectric module arranged further toward the inside radially.

2. The temperature control unit according to claim 1, wherein the media line is bended out of the plane of the spiral and is led out from the base body at the inside.

3. The temperature control unit according to claim 1, wherein the mass ratio of the thermal storage mass of the cooling body to the thermal storage mass of the base body and the media line arranged therein is in the range of 0.5 to 1.

4. The temperature control unit according to claim 3, wherein the mass ratio is 0.75.

5. The temperature control unit according to claim 1, wherein a groove into which the media line is pressed is provided in the base body.

6. The temperature control unit according to claim 1, wherein the base body is surrounded by a base body jacket, wherein a plurality of radial connecting webs which are connected to the base body jacket are arranged over the circumference of the base body.

7. The temperature control unit according to claim 6, wherein the base body jacket is partially hollow.

8. The temperature control unit according to claim 1, wherein a cooling line, through which cooling medium for cooling the cooling body flows as needed, is arranged in the cooling body.

9. The temperature control unit according to claim 8, wherein the cooling line is arranged in the form of a spiral.

10. The temperature control unit according to claim 1, wherein the heating power in the radially outer region of the base body, as the sum of the module heating powers of the thermoelectric modules in the radially outer region, is greater than the heating power in the radially inner region of the base body, as the sum of the module heating powers of the thermoelectric modules in the radially inner region.

11. The temperature control unit according to claim 1, wherein the mass ratio of the thermal storage mass of the cooling body to the thermal storage mass of the base body and the media line arranged therein is in the range of 0.7 to 0.8.

12. The temperature control unit according to claim 2, wherein the mass ratio of the thermal storage mass of the cooling body to the thermal storage mass of the base body and the media line arranged therein is in the range of 0.5 to 1.

13. The temperature control unit according to claim 2, wherein the mass ratio of the thermal storage mass of the cooling body to the thermal storage mass of the base body and the media line arranged therein is in the range of 0.7 to 0.8.
